(19) United States
(12) Patent Application Publication
(10) Pub. No.: US 2026/0255898 A1
(43) Pub. Date: Aug. 27, 2026

(54) PLASMA PROCESS METHOD AND PLASMA PROCESSING DEVICE

(71) Applicant: Advanced Micro-Fabrication Equipment Inc. China, Shanghai (CN)

(72) Inventors: Yichuan ZHANG, Shanghai (CN); Weina XU, Shanghai (CN); Kai ZHANG, Shanghai (CN); Ziyang WU, Shanghai (CN); Jianqiu HOU, Shanghai (CN); Jiqiang GU, Shanghai (CN)

(21) Appl. No.: 19/654,675

(22) Filed: Apr. 22, 2026

Related U.S. Application Data
(63) Continuation of application No. PCT/CN2024/126616, filed on Oct. 23, 2024.

(30) Foreign Application Priority Data
Oct. 27, 2023 (CN) 202311413250.3

(51) Int. Cl. H10P 50/28

(52) U.S. Cl. CPC H10P 50/283

(57) ABSTRACT

The present disclosure provides a plasma process method, which includes: introducing a reaction gas, putting a wafer into a reaction chamber, exciting a plasma, then performing a wafer etching process, and setting the etching process to different processing stages along with the increase of an etching depth, where each processing stage includes an etching step and a modification step, the etching step is used to increase the etching depth, the modification step is used to trim the shape of a side wall of an etched structure, and the temperature of the wafer in each step is gradually increased with the increase of the etching depth. By the process method and the device using the process method, good upper and lower feature size consistency can be ensured when deep hole etching is performed.

### CROSS-REFERENCE TO RELATED APPLICATIONS

This application is a Continuation Application of International Patent Application No. PCT/CN2024/126616, filed on Oct. 23, 2024, which is based on and claims priority to and benefits of Chinese Patent Application No. CN202311413250.3, filed with the China National Intellectual Property Administration on Oct. 27, 2023. The above-referenced applications are incorporated herein by reference in their entirety.

### TECHNICAL FIELD

The present disclosure relates to the technical field of plasma etching, and in particular to a plasma process method and a plasma processing device.

### BACKGROUND

Micro-processing of semiconductor wafers or substrates is a well-known technology, which can be used to manufacture, for example, semiconductors, flat panel displays, light-emitting diodes (LED), solar batteries and the like. An important step of the micro-processing is a plasma process step. The plasma process step is performed inside a reaction chamber, and a process gas is input into the reaction chamber. A radio frequency source is inductively and/or capacitively coupled into the reaction chamber to excite the process gas to form and maintain a plasma.

With the increasing demand for data storage and logic processing ability, an aspect ratio (a ratio of a height of a hole or groove to a horizontal width thereof) of a structure formed on the wafer is getting higher and higher. In the process of forming the high-aspect-ratio structure by plasma etching, the difference between the top and bottom sizes is required to be controlled within a small range. However, in the existing process, when the high-aspect-ratio etching is performed to a certain depth, the horizontal sizes of the uppermost part and the lowermost part will be greatly different, resulting in defective shapes such as an bowing and twisting shape.

### SUMMARY

### Technical Solution

To solve the above technical problems and improve the vertical consistency when a high-aspect-ratio structure is etched, the present disclosure provides a plasma process method, used for etching a wafer and including:
moving the wafer into a reaction chamber, introducing a reaction gas, using a source radio frequency to excite a plasma, and applying a bias radio frequency to perform a first processing stage, where the wafer is etched downward to a first depth in the first processing stage;
the first processing stage includes a first etching step 1, a first modification step 1 and a first etching step 2;
and
a temperature of the wafer in the first etching step 1 is lower than that of the wafer in the first modification step 1, and a temperature of the wafer in the first etching step 2 is higher than that of the wafer in the first etching step 1 and lower than that of the wafer in the first modification step 1.

Optionally, the plasma process method further includes a second processing stage, where in the second processing stage, the wafer is etched downward to a second depth based on the first depth, and the second depth is greater than the first depth; the second processing stage includes a second etching step 1, a second modification step 1 and a second etching step 2, the temperature of the wafer in the second etching step 1 being lower than that of the wafer in the second modification step 1, and the temperature of the wafer in the second etching step 2 being higher than that of the wafer in the second etching step 1 and lower than that of the wafer in the second modification step 1; and an average temperature of the wafer during etching in the first processing stage is controlled to be less than that of the wafer during etching in the second processing stage.

Optionally, in the first processing stage and the second processing stage, a temperature of the wafer is less than 20° C.

Optionally, the source radio frequency and/or the bias radio frequency adopts a pulse mode.

Optionally, a duty ratio of the pulse mode is 5% to 90%.

Optionally, the first processing stage further includes a first etching step n, a first modification step n and a first etching step n+1, where the temperature of the wafer in the first etching step n is lower than that of the wafer in the first modification step n, and the temperature of the wafer in the first etching step n+1 is higher than that of the wafer in the first etching step n and lower than that of the wafer in the first modification step n; and/or the second processing stage further includes a second etching step n, a second modification step n and a second etching step n+1, where the temperature of the wafer in the second etching step n is lower than that of the wafer in the second modification step n, the temperature of the wafer in the second etching step n+1 is higher than that of the wafer in the second etching step n and lower than that of the wafer in the second modification step n, and n is greater than 2; and
in the second processing stage, the second etching step 1 and the second modification step 1 are alternately performed.

Optionally, durations of the first etching step 1, the first modification step 1 and the first etching step 2 respectively range from 0.5 ms to 100 s, and/or durations of the second etching step 1, the second modification step 1 and the second etching step 2 respectively range from 0.5 ms to 100 s.

Optionally, a duration of the first processing stage ranges from 10 s to 1000 s, and/or a duration of the second processing stage ranges from 10 s to 1000 s.

Optionally, the first processing stage uses a same reaction gas, and/or the second processing stage uses a same reaction gas.

Optionally, the reaction gas includes one or more of a hydrofluorocarbon gas, oxygen, hydrogen bromide, carbonyl fluoride, nitrogen trifluoride, hydrogen and phosphorus trifluoride.

Optionally, the wafer includes an alternate stacked layer of silicon oxide and silicon nitride, or an alternate stacked layer of silicon oxide and polysilicon, or a silicon oxide layer.

Optionally, by the process method, a hole with an aspect ratio greater than 40 is formed in the wafer.

Optionally, the sum of power of the source radio frequency and power of the bias radio frequency applied to the reaction chamber in the first etching step 1 is first etching net power, the sum of power of the source radio frequency and power of the bias radio frequency applied to the reaction chamber in the first modification step 1 is first modification net power, and the first etching net power is less than the first modification net power; and the sum of power of the source radio frequency and power of the bias radio frequency applied to the reaction chamber in the second etching step 1 is second etching net power, the sum of power of the source radio frequency and power of the bias radio frequency applied to the reaction chamber in the second modification step 1 is second modification net power, and the second etching net power is less than the second modification net power.

Optionally, a duration of the second modification step 1 is greater than that of the first modification step 1.

Optionally, net power of the first etching step 1 and net power of the second etching step 1 range from 3000 W to 8000 W; and net power of the first modification step 1 and net power of the second modification step 1 range from 8000 W to 14000 W.

Optionally, a longitudinal etching rate of the first etching step 1 is greater than that of the first modification step 1; a longitudinal etching rate of the second etching step 1 is greater than that of the second modification step 1; a transverse etching rate of the first etching step 1 is less than that of the first modification step 1; and a transverse etching rate of the second etching step 1 is less than that of the second modification step 1.

Optionally, the plasma process method further includes a plurality of Nth processing stages after the second processing stage, where N is greater than 2; the Nth processing stage includes an Nth etching step 1, an Nth modification step 1 and an Nth etching step 2; and the temperature of the wafer in the Nth etching step 1 is lower than that of the wafer in the Nth modification step 1, and the temperature of the wafer in the Nth etching step 2 is higher than that of the wafer in the Nth etching step 1 and lower than that of the wafer in the Nth modification step 1.

Optionally, the temperature of the wafer is changed through a thermal conductivity of helium between the wafer and the base and/or a temperature of the base.

Optionally, the temperature of the base in the second processing stage is greater than that of the base in the first processing stage.

Further, the present disclosure further provides a plasma process method, used for processing a wafer and including:
moving the wafer onto a base of a reaction chamber, introducing a reaction gas, using a source radio frequency to excite a plasma and then applying a bias radio frequency, and alternately performing an etching step and a modification step for many times, where a temperature of the wafer in the modification step is greater than that of the wafer in the etching step, the temperature of the wafer in the next etching step is increased after each etching step and modification step, and the temperature of the wafer in the next etching step is lower than that of the wafer in the previous modification step.

Optionally, the sum of power of the source radio frequency and power of the bias radio frequency applied to the reaction chamber in the etching step is etching net power, the sum of power of the source radio frequency and power of the bias radio frequency applied to the reaction chamber in the modification step is modification net power, and the etching net power is less than the modification net power.

Optionally, time of the etching step ranges from 100 ms to 100 s, and/or time of the modification step ranges from 100 ms to 100 s.

Optionally, after the etching step and the modification step are alternately performed for 10 s to 1000 s, the temperature of the base is increased and then the etching process and the modification process are continuously performed alternately.

Optionally, the temperature of the base is less than −30° C.

Optionally, the temperature of the base is increased from 1° C. to 40° C.

Further, the present disclosure further provides a plasma processing device, including:
a reaction chamber, a reaction space being formed inside the reaction chamber to perform plasma processing;
a gas inlet structure, connected to a plurality of gas sources and configured to introduce a reaction gas into the reaction space;
a radio frequency source, including a source radio frequency and a bias radio frequency;
a base, located inside the reaction chamber, an upper surface of the base being configured to support a wafer; and
a controller, configured to control the processing device to perform any one of the above process methods.

Optionally, the base is provided with a temperature regulator with a regulation range of −80° C. to 30° C.

### Beneficial Effects

One of the above technical solutions has the following advantages or beneficial effects: the etching depth is rapidly increased in the longitudinal direction through the etching step, and a side wall protective layer of the target structure is trimmed in the horizontal direction through the modification step; by utilizing the circulation of the etching step and the modification step, the trimming result of the modification step can assist the progress of the next etching step, and compared with no modification step, the etching step can perform the downward etching progress more rapidly; by controlling the time of the etching step and the modification step, the vertical consistency of the shape and the etching efficiency can be taken into consideration, and the etching of the target structure can be completed within the optimized time length; in the technical solutions, by controlling the temperature of the wafer, the wafer is at a relatively low temperature in the etching step and the wafer is at a relatively high temperature in the modification step; and after the modification step and the etching step are alternately performed once, compared with the previous etching step, the temperature in the next etching step is increased and lower than the temperature of the wafer in the previous modification step, so that the temperature of the wafer is increased in a stepwise manner in time, thereby adapting to the requirements on the etching and modification degrees under different etching depths. Meanwhile, in combination with the control of the net power, the temperature of the wafer is increased, compared with the net power required when the constant temperature condition is maintained in the whole process stage, the net power required when the target with the equal depth is etched is reduced, so that under the condition of ensuring the etching and modification effects unchanged, the voltage environment of components in the chamber is reduced, and damage to the components or the wafer due to discharged is avoided. In some technical solutions, from one processing stage to another processing stage, as the etching depth is increased to a certain degree, it is not enough to obtain a better etching effect only by changing the temperature in the etching step and the modification step. At this time, the temperature of the base is increased to adapt to a deeper etching structure; or correspondingly increasing the net power of the etching step and the net power of the modification step can achieve the same etching effect in the deep part of the hole as in the shallow part, combining with the temperature regulation can reduce the increase degree of the net power, and even in some processing stages, the net power of the corresponding step can be kept unchanged through temperature regulation.

### BRIEF DESCRIPTION OF THE DRAWINGS

To describe the technical solutions in the embodiments of the present disclosure or the prior art more clearly, the following briefly introduces the accompanying drawings required for describing the embodiments or the prior art. Apparently, the accompanying drawings in the following description show only some embodiments of the present disclosure, and those of ordinary skill in the art may still derive other drawings from these drawings without any creative work.

FIG. 1 is a structural schematic diagram of a wafer with a part etched by a process method;

FIG. 2A to FIG. 2D are structural schematic diagrams formed in the process of etching a wafer by a process method according to the present disclosure;

FIG. 3 is a structural schematic diagram of a processing method according to the present disclosure applied to another etching object;

FIG. 4A to FIG. 4D are step schematic diagrams of process methods of different embodiments according to the present disclosure;

FIG. 5 is a structural schematic diagram of a plasma processing device applied to a process method according to the present disclosure;

FIG. 6 is a radio frequency schematic diagram of Embodiment 1;

FIG. 7 is a radio frequency schematic diagram of Embodiment 2; and

FIG. 8 is a temperature schematic diagram of Embodiment 5.

### DETAILED DESCRIPTION OF THE EMBODIMENTS

To make objectives, technical solutions and advantages of the embodiments of the present disclosure clearer, the technical solutions in the embodiments of the present disclosure will be clearly and completely described below in conjunction with the drawings of the embodiments of the present disclosure. Obviously, the described embodiments are part of, but not all of, the embodiments of the present disclosure. Based on the embodiments of the present disclosure, all other embodiments obtained by those of ordinary skill in the art without creative work are included in the protection scope of the present disclosure.

FIG. 1 is a structural schematic diagram of a wafer with a part etched by a process method, where the wafer includes a substrate 110 which is usually made of a silicon material, and a layer to be etched 120 formed on the substrate 110; and after a plasma is generated, it is necessary to form a hole or other shapes of structures in the layer to be etched 120. The hole is taken as a representative for description below. A mask layer 130 is arranged on the layer to be etched 120; the mask layer 130 is patterned after the previous process such as a photoetching process, so that one part of the layer to be etched 120 is exposed to be subjected to plasma bombardment and be etched away; and a part covered by the mask layer 130 is protected from bombardment and thus is retained to finally form the required hole. Theoretically, the boundary of the retained part of the layer to be etched 120 strictly corresponds to the boundary of the mask layer 130. However, in the actual plasma processing process, due to the transverse movement of particles, the side wall of the hole will be excessively etched, and finally, the transverse size of the hole is greater than an expected value, resulting in the unqualified process results such as subsequent filling. Therefore, in the actual plasma etching process, in addition to the requirement that the particles can move downward to react with the layer to be etched 120, it is also necessary to form a protective layer 140 on the side wall of the hole. The essence of the protective layer 140 is some hydrocarbon polymers, which can prevent the free radicals in the plasma from reacting with the side wall of the hole so as to avoid transverse etching. However, the following problem is that the thickness uniformity of the protective layer 140 in the vertical direction cannot be ensured. The actual situation is that the protective layer 140 close to the upper part is thicker without changing the process, and the thickness is gradually increased with time to eventually block an opening of the hole and prevent the plasma from etching further downward.

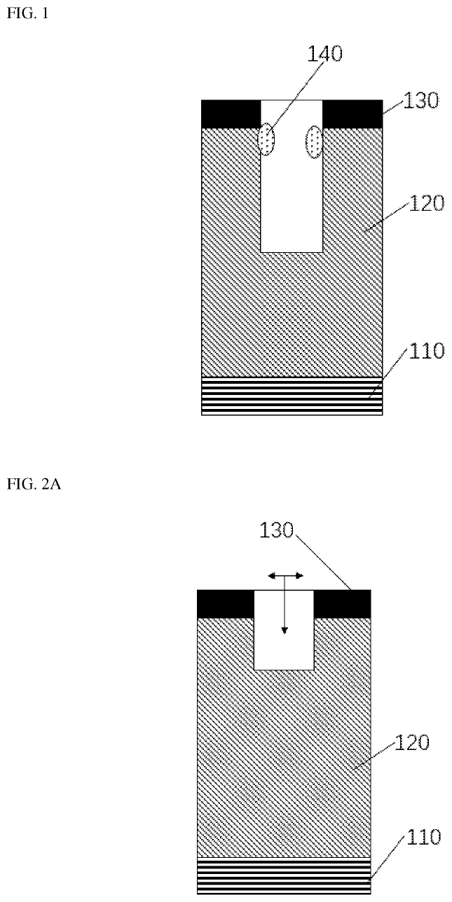

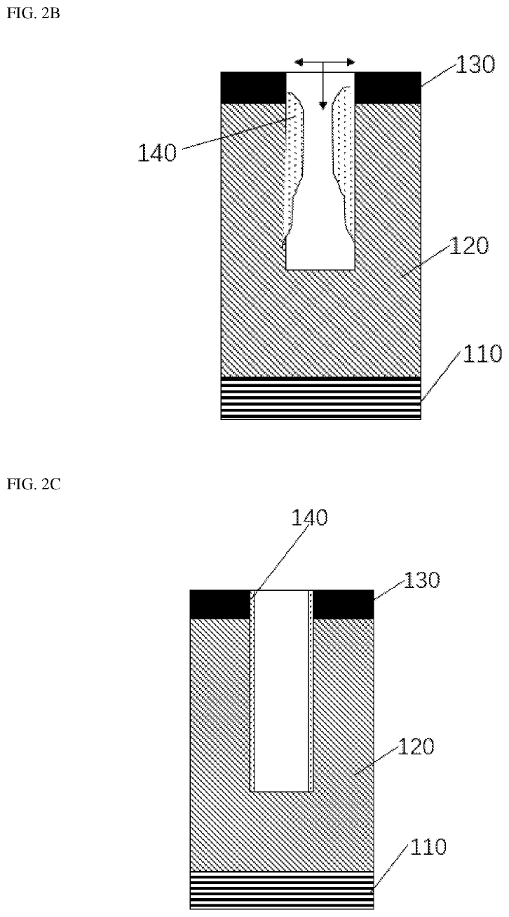

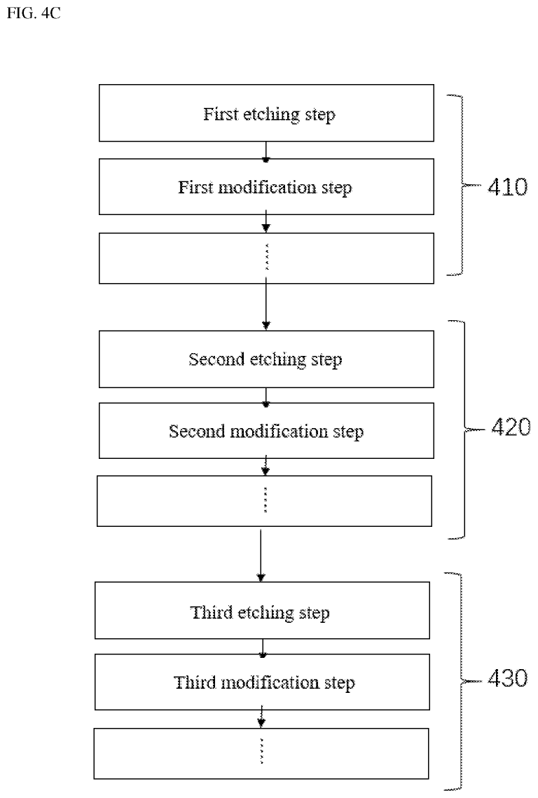

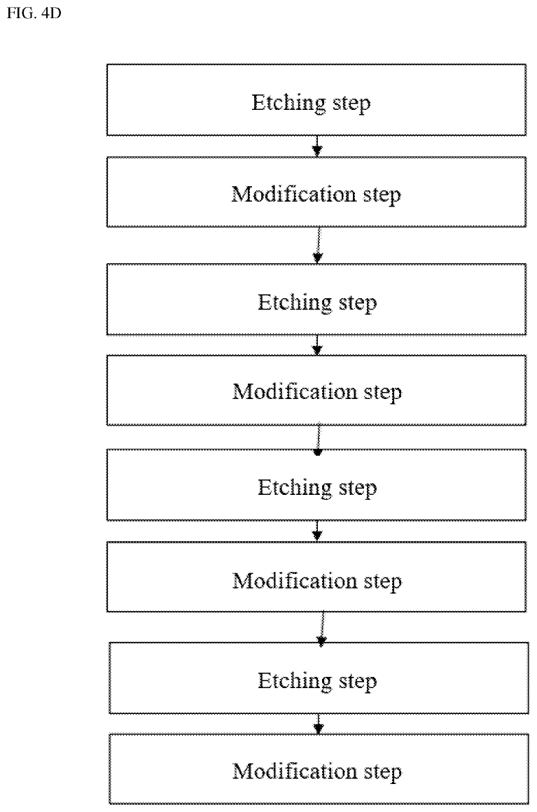

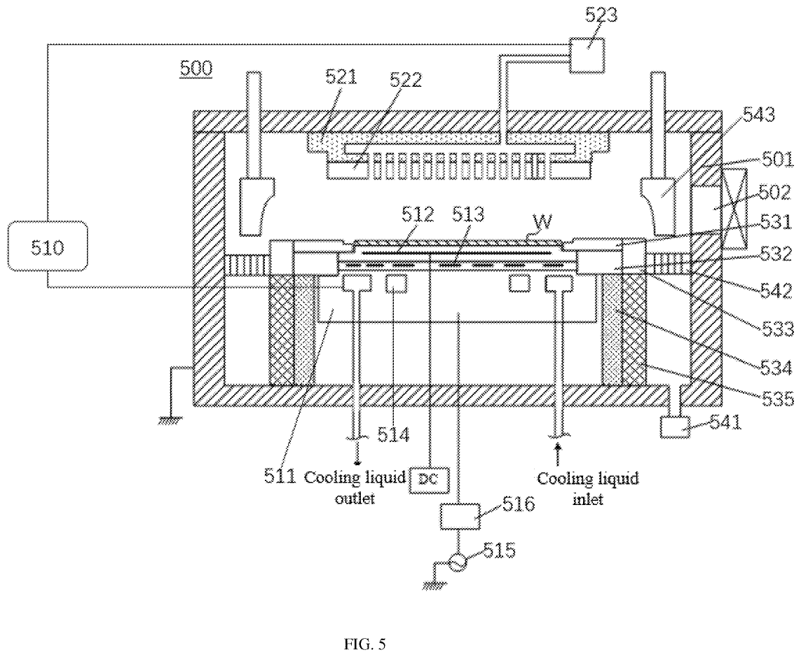

A plasma process method provided by the present disclosure is used for etching a wafer. According to different etching depths, the technical solution of the present disclosure at least includes a first processing stage 410. With the increase of the etching depth, the number of the processing stages can be gradually increased. Taking two processing stages as an example, as shown in FIG. 2A, the wafer includes a substrate 110, a layer to be etched 120 and a mask layer 130. The steps of one embodiment of the process method are shown in FIG. 4A, including: a reaction gas is introduced after the wafer is moved into a reaction chamber, and the reaction gas is selected according to different materials of the layer to be etched 120 to finally achieve high-selectivity etching with the mask layer 130. Then, a source radio frequency is used to excite the reaction gas to form a plasma, the source radio frequency usually has a higher frequency to accelerate the mutual collision of particles in the reaction gas, then a bias radio frequency is applied to perform a first processing stage 410 and a second processing stage 420, and the bias radio frequency usually has a lower frequency and is used to form an electric field to enable charged particles to move toward the wafer and generate a physical or chemical reaction with the layer to be etched 120 to perform an etching process, where a depth to be etched in the second processing stage 420 is greater than that in the first processing stage 410, that is, a hole etched in the layer to be etched 120 has a first depth when the first processing stage 410 ends, the second processing stage 420 continues to etch downward along the first depth based on the first processing stage 410, a hole etched in the layer to be etched 120 has a second depth when the second processing stage 420 ends, and the second depth is greater than the first depth.

Step-by-step etching operations are performed in the first processing stage 410 and the second processing stage 420. To solve the problem of the overall shape of an etched hole structure, each processing stage includes steps with different functions. Specifically, the first processing stage 410 includes a first etching step and a first modification step, where the first etching step may further includes a first etching step 1, a first etching step 2 or a first etching step n by analogy, the first modification step may further include a first modification step 1, a first modification step 2 or a first modification step n by analogy, and n is greater than 2; and the second processing stage 420 includes a second etching step and a second modification step, where the second etching step may further include a second etching step 1, a second etching step 2 or a second etching step n by analogy, the second modification step may further include a second modification step 1, a second modification step 2 or a second modification step n by analogy, and n is greater than 2. The etching step and the modification step of the present disclosure have etching rates greater than 0 in the longitudinal direction and the transverse direction, respectively. However, the longitudinal etching rate is much greater than the transverse etching rate in the etching step, and the transverse etching rate is increased and the longitudinal etching rate is reduced in the modification step. Meanwhile, the longitudinal etching rates of the first etching step and the second etching step are greater than those of the first modification step and the second modification step, and the transverse etching rates of the first etching step and the second etching step are less than those of the first modification step and the second modification step. Therefore, a step primarily focused on downward etching is performed for a certain time and then a step primarily focused on lateral modification is performed for a certain time within the same processing stage, and the etching and modification steps are repeated within another processing stage.

In this embodiment, the temperature of the wafer of the first modification step is greater than that of the wafer of the first etching step; however, with the increase of the etching depth, it is more difficult to perform downward etching and lateral modification; according to the influence of the temperature on the degree of the chemical or physical reaction, the mechanism of the longitudinal etching is mainly accelerated by the directionality of the bias radio frequency, the particles from the plasma are attached to the bottom hole to react with the etched target, even if a small amount of protective layer at the bottom of the hole is etched away; and the transverse etching is not accelerated by bias and mainly depends on the isotropic movement of the particles attached to the side wall of the hole for reaction, but the protective layer is deposited on the side wall, so the transverse etching rate is significantly weaker than the longitudinal etching rate. The increase of the temperature will accelerate the movement of the particles. In the longitudinal direction, the kinetic energy of the particles for etching is increased, the adsorption capacity at the bottom of the hole is reduced, and correspondingly, the longitudinal etching rate will be reduced. In the transverse direction, since the absorption capacity of the protective particles is correspondingly reduced to reduce the protection ability, although the absorption capacity of the particles for transverse etching is also reduced, the synthetic action of the two leads to the increase of the transverse etching rate due to the more reduced protection degree brought by the reduced adsorption capacity of the protective particles. To obtain the same downward etching progress within the same time, taking the first processing stage as an example, when the first etching step 2 is performed, the temperature of the wafer in the first etching step 2 is increased to be higher than that in the first etching step 1, and the downward etching ability is improved; however, the temperature of the wafer in the first etching step 2 is controlled to be lower than that in the first modification step 1 because the etching depth is similar in the same processing stage; and if the temperature of the wafer in the first etching step 2 is increased too much, the effect approaching the modification step in the same processing stage will be generated, that is, the transverse etching rate is too high, which is not conducive to the control progress of the overall shape.

In some embodiments, the base for supporting the wafer has cooling and heating functions, and the temperature range of the base has a large regulation window, which can be regulated between −80° C. and 30° C. Meanwhile, thermal conduction between an upper surface of the base and a lower surface of the wafer is achieved through helium, the thermal conduction efficiencies of the etching step and the modification step can be regulated by changing the pressure of the helium between the wafer and the base or regulating the flow of the helium in a pipeline, thereby changing the temperature of the wafer in different steps. The temperature of the wafer can be regulated rapidly by changing the pressure of the helium between the base and the wafer. For example, increasing the pressure of the helium can improve the cooling efficiency of the wafer and reduce the temperature of the wafer, and the range of the temperature of the wafer can be changed from 0° C. to 50° C. by regulating the pressure of the helium. With the increase of the etching depth, when it is difficult to reach the required temperature of the wafer by regulating the pressure of the helium, in order to increase the temperature of the base, the processing process can be regulated from the first processing stage to the second processing stage, that is, the temperature of the base in the second processing stage is higher than that of the base in the first processing stage. Of course, in other embodiments, the temperature of the base and/or the pressure of the helium can be regulated in each etching step or modification step unit to finally meet the requirements on the temperature of the wafer in the etching step and the modification step.

In some technical solutions of the present disclosure, an average temperature in the first processing stage is different from that in the second processing stage. Specifically, the average temperature of the wafer during etching in the first processing stage is less than that of the wafer during etching in the second processing stage. In some embodiments, based on the above technical solutions, the influences of the etching step and the modification step on the temperature of the wafer are superimposed by actively increasing the temperature of the base, so that the average temperature of the wafer during etching in the first processing stage is less than that of the wafer during etching in the second processing stage. The average temperature of the wafer is a ratio of the sum of products of different temperatures and durations thereof to the time when the wafer has different temperatures within a period of time, which reflects the average temperature within the period of time.

Since during the process, in addition to being formed by directly depositing a reaction product on the side wall, the protective layer is also formed by attaching a byproduct etched from the bottom of the hole to the side wall when moving out of the hole, under the condition that the viscosity of the byproduct is unchanged, with the increase of the etching depth, more and more byproducts move upward from the bottom; furthermore, the movement distance is increased, so that the deposition probability of these byproducts on the side wall of the hole is increased; if other conditions of the etching step and the modification step are not changed, the shape of the hole will also deteriorate, and the viscosities of the protective layer component from the reaction product and the protective layer component from the bottom byproducts are affected by the temperature; when the temperature is increased, the viscosity will be reduced; therefore, in the technical solution of the present disclosure, with the increase of the etching depth, the temperature of the base is increased, so that the viscosity of the component of the protective layer is reduced; and the components of the protective layer become more with the increase of the etching depth, so the strength of the protective layer can be maintained basically the same as a whole, and the basically same effect of regulating the shape is achieved in the etching step and the modification step at different etching depths.

In some other embodiments, the processing stage may include not only the first processing stage and the second processing stage, but also third and fourth processing stages that are gradually increased based on the second processing stage and are arranged backward sequentially according to an Nth processing stage, where N is greater than 2. Each processing stage includes an etching step and a modification step, and with the increase of the etching depth, the temperature of the wafer in each processing stage is gradually increased. Meanwhile, the temperature of the wafer in each processing stage may be increased differently, depending on the specific process target.

In the technical solution of the present disclosure, in addition to controlling the temperature of the wafer differently, the etching step and the modification step may also change other process conditions, for example, change the types of the reaction gases, change the flow of the reaction gas, change the pressure of the chamber, change the frequency or power of the radio frequency, or introduce other means such as laser assistance and magnetic field assistance.

Taking the change of the power of the radio frequency as an example, the power of the first processing stage 410 includes a first etching step and a first modification step. If the sum of the effective power of power of the source radio frequency and power of the bias radio frequency within a period of time is recorded as net power, the first etching step has first etching net power, and the first modification step has first modification net power. The difference between the first etching step and the first modification step is that the first etching net power is less than the first modification net power.

In the first etching step, as shown in FIG. 2A to FIG. 2B, the plasma will form a protective layer 140 on a side wall of the hole as the reaction time goes on, but the closer to the orifice is, the more polymer is deposited, resulting in a thicker protective layer 140 at the position; the first etching net power is increased to the first modification net power, energy obtained by the particles in the plasma is enhanced within the same time, higher isotropic kinetic energy is obtained, and stronger bombardment can occur in the transverse direction, so that the surface polymer of the protective layer 140 is bombarded; and similarly, since the particles move from top to bottom, the polymer closer to the upper part is more likely to be bombarded, thereby finally modifying the protective layer 140 and obtaining the etching result shown in FIG. 2C.

Then, the second processing stage 420 is performed and includes a second etching step and a second modification step. The second etching step has second etching net power, and the second modification step has second modification net power, where the second etching net power is less than the second modification net power. After the second etching step is continuously performed based on the first processing stage 410, the etching result shown in FIG. 2D will be formed. The non-uniform protective layer 140 will occur again close to the orifice. At this time, the second etching net power is increased to the second modification net power to perform the second modification step, and the redundant polymer at the orifice is bombarded to modify the shape of the protective layer 140.

In conclusion, during the process, the transverse etching and the longitudinal etching always exist at the same time, as shown in arrow vectors in FIG. 2A to FIG. 2B, the direction of the arrow represents the etching direction, and the length of the arrow represents the etching rate. However, by regulating the net power, the longitudinal etching rates of the first etching step and the second etching step are greater than those of the first modification step and the second modification step, and the transverse etching rates of the first etching step and the second etching step are less than those of the first modification step and the second modification step. In this way, the first etching step and the second etching step mainly have the effect of etching the wafer downward, and the first modification step and the second modification step mainly play a role in flattening the side wall protective layer of the hole.

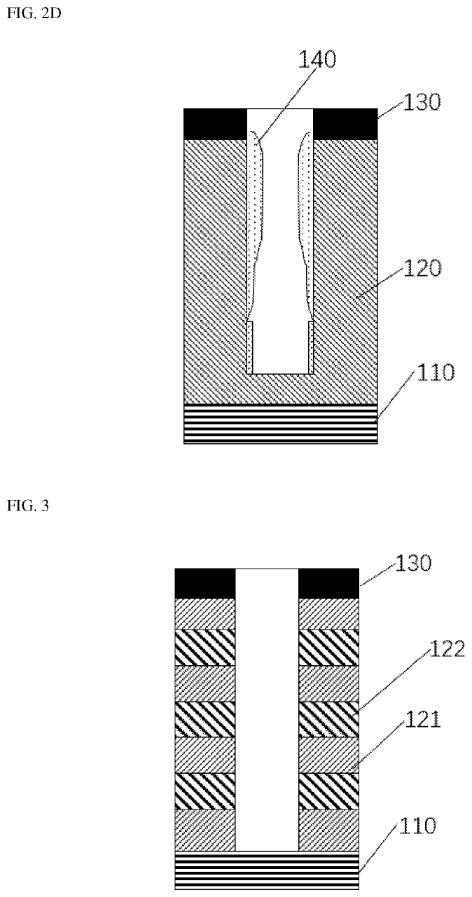

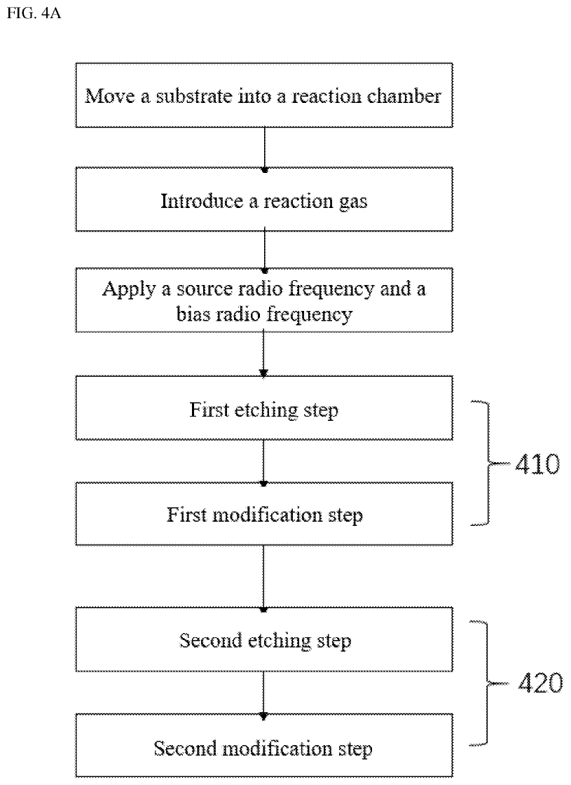

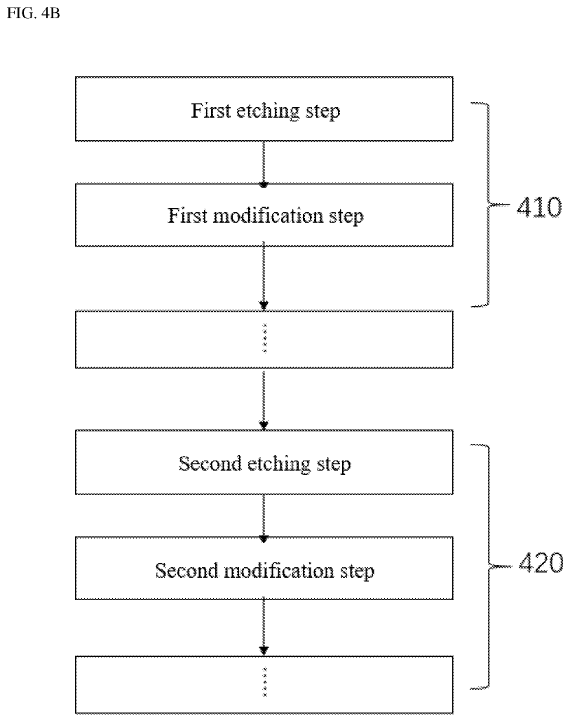

In some embodiments, a material of the substrate 110 may be silicon and may also be sapphire, silicon carbide, germanium and gallium that may serve as a material of a semiconductor process; and the layer to be etched 120 may be the same material, such as silicon dioxide, silicon nitride, monocrystalline silicon, polycrystalline silicon or the above-mentioned doped materials, and may also be an alternate stack of any two of silicon dioxide, silicon nitride and polycrystalline silicon, in one embodiment shown in FIG. 3, the layer to be etched 120 is an alternate stack of a silicon dioxide layer 121 and a silicon nitride layer 122.

Since when the plasma is used for etching, as the etching depth goes on, in addition to the polymer in the plasma deposited on the side wall of the hole to form the protective layer 140, a byproduct of the material of the layer to be etched 120 reacting with the plasma will be deposited on the side wall of the hole to form one part of the protective layer 140 in the process of being pumped out of the hole, and at this time, compared with the modification step in the previous stage, the net power value of the next modification step can be increased, thereby improving the bombardment effect and modifying the protective layer 140 within the same time. However, excessively high net power will increase the risk of damage to various components in a chamber, and put forward higher requirements on the design of the chamber and the materials of the components, which is not conducive to the cost reduction and mass production promotion of products. In some other embodiments of the present disclosure, the temperature of the wafer in the second processing stage 420 is set to be higher than the temperature of the wafer in the first processing stage 410; when the temperature of the wafer is increased, the byproduct of the reaction and the polymer in the plasma obtain energy to have higher activity, that is, have lower viscosity; however, since the hole etched in the second processing stage 420 is deeper, the byproduct is more difficult to be pumped away, resulting in more raw materials forming the protective layer 140, so although the viscosity is reduced, the thickness of the protective layer 140 can be maintained at a certain value, which is enough to protect the side wall. Therefore, in the second process stage 420, although the etching depth is increased, a sufficient modification effect can be achieved without greatly increasing the radio frequency net power. In some embodiments, the temperature of the wafer is increased, but it is necessary to control the temperature of the wafer to be less than 20° C. all the time. Excessively high temperature will significantly reduce the protective effectiveness of the protective layer.

In some other embodiments, the difference from the above embodiments is that, as shown in FIG. 4B, the first processing stage 410 of the present disclosure includes a plurality of first etching steps and first modification steps performed alternately, and similarly, the second processing stage 420 may also include a plurality of second etching steps and second modification steps performed alternately. In one embodiment, the bias radio frequency and/or the source radio frequency adopts a pulse mode, the duty ratio of the pulse mode may be 5% to 90%, the pulse mode here is a pulse modulated based on an inherent frequency of a radio frequency power supply, that is, the frequency of the radio frequency power supply is temporarily ignored, the radio frequency is modulated into a pulse, and the electromagnetic mode is the pulse mode after the frequency of the radio frequency is superposed with the modulated frequency. In the first processing stage or the second processing stage, the first etching step or the second etching step is corresponded when the pulse mode is at the low-power position, and the first modification step or the second modification step is corresponded when the pulse mode is at the high-power position. For example, the cycle of the pulse mode is set between 0.5 ms and 100 ms, and the time of each step ranges from 0.5 ms to 100 ms. In the processing stage (the first processing stage or the second processing stage), the step (the first etching step, the second etching step, the first modification step or the second modification step) may respectively include cyclic circulation of a plurality of pulse radio frequencies, the difference between different steps is regulated by regulating the net power of the pulse circulation in each step, and the calculation of the net power of the pulse radio frequency can be determined by the product of high and low power values and the corresponding duty ratios. In this embodiment, the sum of time of the etching step and the modification step is the cycle of the pulse mode, but according to the requirements of the actual process, the time between different steps may be different, and the pulse cycle in each step may also be regulated. The time of each stage is 10 s to 1000 s.

In some other embodiments, the difference from the above embodiments is that the bias radio frequency and/or the source radio frequency adopts a pulse mode, but each step includes a plurality of pulse cycles, for example, the cycle of the pulse mode may be set between 0.5 ms and 100 ms, the time of each step ranges from 100 ms to 100 s, the pulse modes that can be included between different steps has the same maximum and minimum power, the net power is changed by regulating the duty ratios of the pulses between different steps, for example, in the same processing stage, the etching step and the modification step have the same maximum and minimum power, but the maximum power of the modification step has a larger duty ratio, so when the net power is calculated, the modification step obtains higher net power.

In other embodiments, the difference from the above embodiments is that the source radio frequency and/or the bias radio frequency may also be a continuous mode, and a waveform thereof may be sinusoidal, linear or fixed. Correspondingly, a duration of each step is 100 ms to 100 s. The time of each stage is 10 s to 1000 s. When the net power is calculated, compared with the pulse mode, the duty ratio is not required to participate in the calculation. Through comparison between the continuous mode and the pulse mode, the duration of the same step is longer, so the maximum instantaneous power of the continuous mode is less than that of the pulse mode to reduce the risk of damage to the components in the chamber. According to different process requirements, the durations and the net power values between different steps may be different.

In some other embodiments, the difference from the above embodiments is that to finally obtain a hole with a sufficient aspect ratio, such as a hole with an aspect ratio greater than 40, as shown in FIG. 4C, the plasma process method may include a plurality of processing stages, such as a third processing stage 430, or more than three processing stages are continuously added. The third processing stage 430 also includes a third etching step and a third modification step or alternate circulation of the two. To reduce the risk of damage to the chamber by high net power, the temperature of the processing stage (the first processing stage, the second processing stage, the third processing stage or the subsequent processing stage) can be increased step by step. The temperature of the wafer is ensured to be always less than 20° C.

In some embodiments, a gas used for plasma processing may be one or more of a hydrofluorocarbon gas, oxygen, hydrogen bromide, carbonyl fluoride, nitrogen trifluoride, hydrogen and phosphorus trifluoride. The used hydrofluorocarbon gas may be one or more of CH₂F₂, CH₃F, C₂HF₅, C₃HF₅, C₃H₂F₄, C₃H₂F₆, C₄H₂F₆ and C₄F₈.

In some embodiments, the source radio frequency has a frequency ranging from 13 MHz to 120 MHz, and power ranging from 500 W to 8000 W; and the bias radio frequency has a frequency ranging from 50 kHz to 2 MHz, and power ranging from 1000 W to 34000 W. The net power of the etching step ranges from 3000 W to 8000 W, and the net power of the modification step ranges from 8000 W to 14000 W.

The present disclosure further provides another plasma process method, as shown in FIG. 4D, different from the above embodiments in that: the wafer is moved onto a base of a reaction chamber, then a reaction gas is introduced, a source radio frequency is used to excite a plasma and then a bias radio frequency is applied, and an etching step and a modification step are circularly performed, where in the etching step, the sum of power of the source radio frequency and power of the bias radio frequency applied to the reaction chamber is etching net power; in the modification step, the sum of power of the source radio frequency and power of the bias radio frequency applied to the reaction chamber is modification net power; and the etching net power is less than the modification net power. The etching step is mainly used to push down the depth of the hole, and the modification step is mainly used to trim the shape of the protective layer to enable the protective layer not to hinder the downward etching. After the etching step and the modification step are circulated at least once, for example, after the etching step, the modification step, the etching step and the modification step are performed, the temperature of the base is increased and then the etching step and the modification step are continuously circulated. A temperature regulation value of each base heating operation is 1° C. to 40° C., and the temperature of the base is always kept below −30° C. In this way, the etching step and the modification step can be ensured to cooperate with the temperature, and a hole with a good side wall shape is finally obtained. An excessively large or small regulation value will cause the thickness of the protective layer to deviate from a threshold, thereby affecting the synergistic effect with the etching step and the modification step.

### Embodiment 1

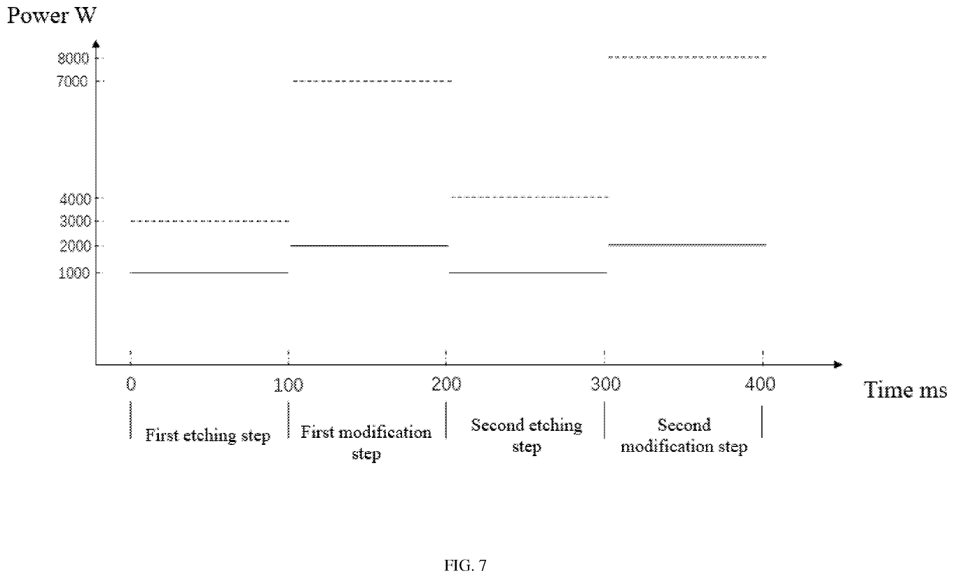

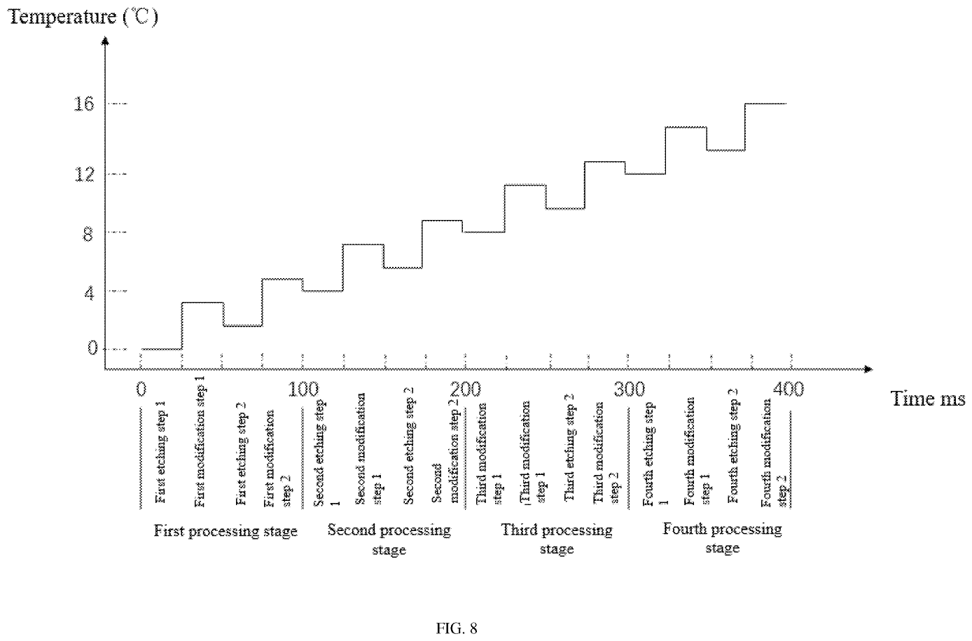

As shown in FIG. 6, in this embodiment, a source radio frequency and a bias radio frequency select a pulse mode; the source radio frequency has a frequency of 60 MHz, maximum power of 5000 W, minimum power of 500 W and a waveform shown in the solid line in FIG. 6; and the bias radio frequency has a frequency of 400 KHz, maximum power of 30000 W, minimum power of 1000 W and a waveform shown in the dotted line in FIG. 6. The temperature of a base is −60° C. If the duty ratio of the source radio frequency is 25% and the duty ratio of the bias radio frequency is 5% in a first etching step, in the first etching step, the value of net power is 5000*25%+500*(1−25%)+30000*5%+1000*(1−5%)=4075, with the unit of W; if the duty ratio of the source radio frequency is 30% and the duty ratio of the bias radio frequency is 21% in a first modification step, the value of the net power can be calculated as 8940 W similarly; if the duty ratio of the source radio frequency is 25% and the duty ratio of the bias radio frequency is 8% in a second etching step, the value of the net power can be calculated as 4945 W similarly; and if the duty ratio of the source radio frequency is 30% and the duty ratio of the bias radio frequency is 25% in a second modification step, the net power can be calculated as 10100 W similarly.

The following data is obtained:

| First Processing Stage | | Second Processing Stage | | | |
|---|---|---|---|---|---|
| (Temperature: −60° C.) | | (Temperature: −60° C.) | | | |
| First | First | Second | Second | Aspect | |
| etching | modification | etching | modification | ratio | CD |
| step | step | step | step | of hole | difference |
| Net power | Net power | Net power | Net power | 50 | 40 nm |
| value: | value: | value: | value: | | |
| 4075 W | 8940 W | 4945 W | 10100 W | | |

In this embodiment, in the same processing stage, the net power value of the modification step is greater than that of the etching step; with the increase of the etching depth, in the adjacent processing stage, the total net power of the etching step and the modification step is increased due to the etching from top to bottom; after the depth is increased, the etching rate and the modification rate are required to be increased correspondingly to achieve better shape consistency of an etching target within unit time. The critical dimension (CD) difference between the upper part and the bottom of the hole after etching is 40 nm, and is significantly increased compared with the prior art without changing the net power.

The net power is changed by changing the duty ratio in this embodiment and by changing the maximum or minimum of the radio frequency power in other embodiments. In addition, the bias radio frequency and the source radio frequency have substantially the same phase in this embodiment, and may have different phases in other embodiments, which has no influence on the calculation of the net power; and when the phases are the same, the synchronized phases are more likely to couple energy to the plasma within a certain period of time.

### Embodiment 2

As shown in FIG. 7, this embodiment is different from Embodiment 1 in that: a source radio frequency and a bias radio frequency select a continuous radio frequency, the source radio frequency has a frequency of 60 MHz, and the bias radio frequency has a frequency of 400 KHz. If the power of the source radio frequency is 1000 W and the power of the bias radio frequency is 3000 W in a first etching step, in the first etching step, the value of net power is the sum (4000 W) of power of the source radio frequency and the bias radio frequency; if the power of the source radio frequency is 2000 W and the power of the bias radio frequency is 7000 W in a first modification step, the value of the net power can be calculated as 9000 W similarly; if the power of the source radio frequency is 1000 W and the power of the bias radio frequency is 4000 W in a second etching step, the value of the net power can be calculated as 5000 W similarly; and if the power of the source radio frequency is 2000 W and the power of the bias radio frequency is 8000 W in a second modification step, the net power can be calculated as 10000 W similarly. In this embodiment, in the first processing stage, when the first etching step is switched to the second etching step, the power of the source radio frequency and the power of the bias radio frequency are increased simultaneously, but the power of the bias radio frequency is increased to a greater extent because the source radio frequency is mainly used to maintain the stability of the plasma and the bias radio frequency is mainly used to give directionality to charged particles to move toward the wafer; and to maintain the plasma density basically stable, the power of the source radio frequency changes little, and regulating the power of the bias radio frequency has little influence on the plasma density. In other embodiments, the power of the source radio frequency can also be greatly changed without affecting the overall etching result. Meanwhile, in the second processing stage, through comparison between the second etching stage and the first etching step in the first processing stage as well as between the second modification step and the first modification step in the first processing stage, the power of the bias radio frequency is increased because the downward etching ability and the lateral modification ability are required to be improved correspondingly when the etching depth is increased, the corresponding power is higher compared with that in the first stage.

The following data is obtained:

| First Processing Stage | | Second Processing Stage | | | |
|---|---|---|---|---|---|
| (Temperature: −60° C.) | | (Temperature: −60° C.) | | | |
| First | First | Second | Second | Aspect | |
| etching | modification | etching | modification | ratio | CD |
| step | step | step | step | of hole | difference |
| Net power | Net power | Net power | Net power | 50 | 40 nm |
| value: | value: | value: | value: | | |
| 4000 W | 9000 W | 5000 W | 10000 W | | |

When the continuous radio frequency is used, the same net power value as the pulse radio frequency can be obtained in the corresponding step by controlling the power values of the source radio frequency and the bias radio frequency; however, in the corresponding step, the instantaneous power value of the continuous radio frequency can be correspondingly reduced compared with the pulse mode, so as to reduce the burden of the device; meanwhile, in some cases, such as the specification limitation of the radio frequency source, the basically same etching result can be provided in the case of the radio frequency source.

### Embodiment 3

This embodiment is different from Embodiment 1 in that: in different processing stages, the temperature of a base is changed to obtain the following data:

| First Processing Stage | | Second Processing Stage | | | |
|---|---|---|---|---|---|
| (Temperature: −60° C.) | | (Temperature: −50° C.) | | | |
| First | First | Second | Second | Aspect | |
| etching | modification | etching | modification | ratio | CD |
| step | step | step | step | of hole | difference |
| Net power | Net power | Net power | Net power | 70 | 30 nm |
| value: | value: | value: | value: | | |
| 4075 W | 8940 W | 4945 W | 10100 W | | |

With the increase of the etching depth, reaction substances in the hole are more difficult to be discharged and are easy to deposit on the side wall to hinder the etching process; the temperature of the base is increased from −60° C. to −50° C., the kinetic energy of different particles is improved, and the viscosity is reduced, so that the substances are easier to be discharged out of the hole, and good vertical consistency of the critical dimension can also be achieved in the same processing stage even the net power is maintained unchanged. The critical dimension difference (CD difference) of the upper part and the bottom of the hole after etching can be reduced to 30 nm.

### Embodiment 4

This embodiment is different from Embodiment 3 in that a plurality of processing stages are included; and in each processing stage, the etching step and the modification step are circulated, the temperature in the adjacent processing stage is increased, and the time of different steps is regulated. The following data is obtained:

in the first processing stage, the temperature of a base is set as −50° C. and the overall processing stage lasts for 600 s, and in this processing stage, a first etching step and a first modification step are circulated, the first etching step has net power of 4000 W and lasts for 3 s, and the first modification step has net power of 9000 W and lasts for 3 s; in the second processing stage, the temperature of the base is set as −40° C. and the overall processing stage lasts for 600 s, and in this processing stage, a second etching step and a second modification step are circulated, the second etching step has net power of 5000 W and lasts for 3 s, and the second modification step has net power of 10000 W and lasts for 5 s; and in the third processing stage, the temperature of the base is set as −30° C. and the overall processing stage lasts for 600 s, and in this processing stage, a third etching step and a third modification step are circulated, the third etching step has net power of 5000 W and lasts for 3 s, and the third modification step has net power of 10000 W and lasts for 9 s. With the increase of the etching depth, the trimming of the side wall becomes more and more difficult, and it is necessary to prolong the modification time. In other embodiments, according to the etching requirement, the number of the processing stages may also be continuously increased, and the temperatures of the base in each processing stage are different. Through the above parameters and steps, the etching result with the CD difference of 30 nm can be finally achieved in the hole structure with the aspect ratio of 60 or more.

### Embodiment 5

In this embodiment, four processing stages are included, each processing stage includes two etching steps and two modification steps that are alternately performed, each processing stage lasts for 100 ms, and each step lasts for 25 ms; and in other embodiments, the processing stages and the number of the steps included, and the duration of each step may be different. The temperature of the wafer is controlled by the pressure of the helium. When the pressure of the helium is increased, the thermal conduction of the wafer and the base is increased, the base can rapidly reach thermal balance with the wafer, and at this time, the base can reach an approximate temperature range through heating or cooling. The temperature of the wafer is finely regulated by the helium, so that the flow of the helium can also be reduced. In this embodiment, the temperature of the base is lower than that of the wafer; and in the first processing stage, the first etching step 1 at about 0° C., the first modification step 1 at about 3° C. after the pressure of the helium is reduced, the first etching step 2 at about 1° C. after the pressure of the helium is increased, and the first modification step 2 at about 5° C. after the pressure of the helium is further reduced are performed sequentially. Etching and modification are performed simultaneously during etching to a first depth, thereby ensuring good shape control at the first depth. When the second processing stage is performed on this basis, with the increased of the etching target depth, the etching difficulty is increased, and it is necessary to increase the temperature of the wafer. Therefore, the second processing stage is different from the first processing stage in that the temperature of the base is increased, so that the second etching step 1 at 4° C. is increased by 2° C. compared with the first etching step 2, which is greater than 1° C. increased in the first etching step 2 relative to the first etching step 1. The third processing stage and the fourth processing stage are similar to the above technical solutions. The overall shape consistency when the hole structure with high aspect ratio is etched is finally improved.

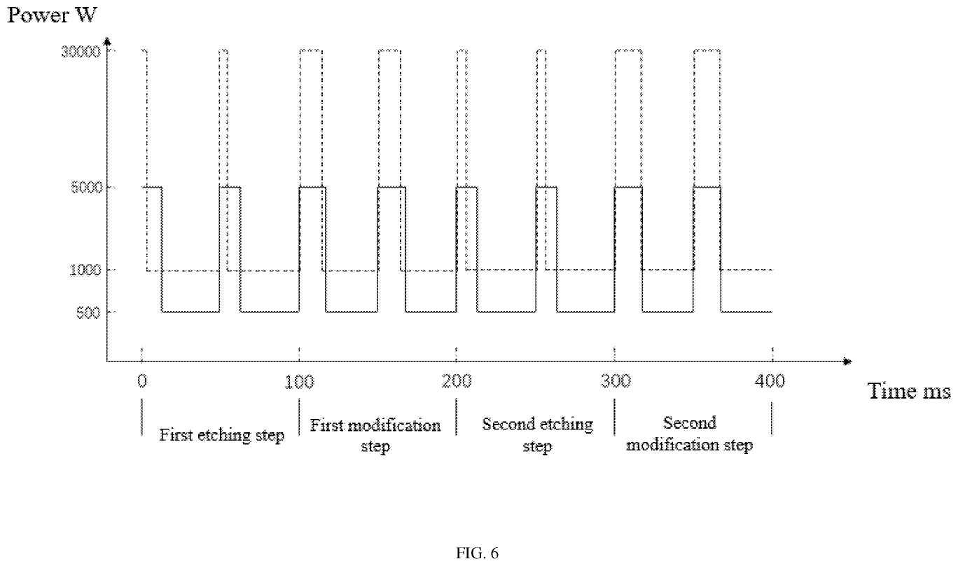

FIG. 5 shows a structural schematic diagram of a capacitively coupled plasma (CCP) etching device. The CCP etching device is a device that generates a plasma in a reaction chamber through capacitive coupling and by a radio frequency power supply applied to a polar plate and uses the plasma for etching. The CCP etching device includes a reaction chamber 500, and a reaction space for performing plasma processing is formed inside the reaction chamber 500. In some embodiments, the reaction chamber 500 includes a reaction chamber side wall 501 that is made of a metal material and is approximately cylindrical, and an opening 502 is formed in the reaction chamber side wall 501 to allow the wafer to be transferred in and out. A gas inlet structure is arranged on an upper part of the reaction chamber, connected to a gas source 523 and the reaction space, and used to input a reaction gas into the reaction chamber 500. Specifically, the gas inlet structure includes a gas spray head 522 and a mounting base plate 521 connected to the spray head 522 and a top wall of the reaction chamber 500. A base 511 arranged opposite to the gas spray head 522 is further arranged in the reaction chamber 500, the gas spray head 522 is also used as an upper electrode of the reaction chamber 500, an electrostatic chuck is arranged above the base 511 and is also used as a lower electrode of the reaction chamber 500, and a reaction area is between the upper electrode and the lower electrode. At least one radio frequency power supply 515 is applied to the upper electrode or the lower electrode through a matched network 516, a radio frequency electric field is generated between the upper electrode and the lower electrode, a radio frequency source may include a source radio frequency and a bias radio frequency, the source radio frequency is used to dissociate the reaction gas into a plasma, the plasma includes a large number of active particles such as electrons, ions, excited atoms, molecules and free radicals, the above active particles can undergo various physical and chemical reactions with the surface of the wafer to be processed, so that the shape of the surface of the wafer changes, the etching process is completed, and the bias radio frequency is used to control the movement direction of the plasma. A controller 510 is used to perform the steps of the above process method.

In some embodiments, the base 511 is internally provided with a temperature regulator, and specifically may include a fluid channel 514 and a circulation structure thereof, into which cooling liquid can be introduced, so that the temperature of the base 511 is reduced or increased, and the controlled temperature of the base 511 changes from −80° C. to 30° C. The temperature regulator and the gas source 523 are jointly regulated by the controller 510 to switch different process steps. A helium channel passes through the base 511 to the back side of the wafer W, and the flow of the introduced helium can be controlled through an external helium source 523, so that the pressure of the helium between the wafer and the base 511 is controlled.

An exhaust pump 541 is arranged below the reaction chamber 500 and used to discharge a reaction byproduct out of the reaction chamber to maintain the vacuum environment of the reaction chamber. An electrostatic electrode 512 is arranged inside the electrostatic chuck and used to generate electrostatic attraction to support and fix the wafer to be processed W during the process. A heating apparatus 513 is arranged below the electrostatic chuck and used to control the temperature of the wafer during the process. A focusing ring 531 and an edge ring 532 are arranged around the base 511, and the focusing ring 531 and the edge ring 532 are used to regulate the electric field or temperature distribution around the wafer and improve the wafer processing uniformity. A protective ring 533 is arranged on a horizontal outer side of the focusing ring 531. A plasma confinement ring 542 is arranged around the protective ring 533, and an exhaust channel is formed in the plasma confinement ring 542. By reasonably setting the aspect ratio of the exhaust channel, the plasma is confined in the reaction area between the upper and lower electrodes while the reaction gas is discharged, so that damage to components in a non-reaction area caused by leakage of the plasma to the non-reaction area is avoided. A lifting ring 543 is arranged above the plasma confinement ring 542 and used to protect the side wall from plasma bombardment. A middle grounding ring is arranged below the plasma confinement ring 542 and used to provide electric field shielding for the plasma confinement ring 542; a lower grounding ring 535 is arranged below the middle grounding ring; and the middle grounding ring maintains electrical connection with the lower grounding ring 535 to form a radio frequency grounding loop in the reaction chamber. A shielding ring 534 is arranged between the lower grounding ring 535 and the base 511 and used to shield a radio frequency signal applied to the base 511 in the base 511 to achieve the electrical isolation between the base 511 and the lower grounding ring 535.

The plasma processing device disclosed by the present disclosure is not limited to the above CCP plasma processing device, but can be suitable for other plasma processing devices, which will not be elaborated here.

Although the content of the present disclosure has been described in detail through the aforementioned preferred embodiments, it should be recognized that the above description should not be considered as limiting the present disclosure. Various modifications and replacements to the present disclosure will become apparent to those skilled in the art upon reading the foregoing content. Accordingly, the protection scope of the present disclosure shall be limited by the appended claims.

1. A plasma process method, used for etching a wafer and comprising:
moving the wafer into a reaction chamber, introducing a reaction gas, using a source radio frequency to excite a plasma, and applying a bias radio frequency to perform a first processing stage, wherein the wafer is etched downward to a first depth in the first processing stage;
the first processing stage comprises a first etching step 1, a first modification step 1 and a first etching step 2;
and
a temperature of the wafer in the first etching step 1 is lower than that of the wafer in the first modification step 1, and a temperature of the wafer in the first etching step 2 is higher than that of the wafer in the first etching step 1 and lower than that of the wafer in the first modification step 1.

2. The plasma process method according to claim 1, further comprising a second processing stage, wherein in the second processing stage, the wafer is etched downward to a second depth based on the first depth, and the second depth is greater than the first depth; the second processing stage comprises a second etching step 1, a second modification step 1 and a second etching step 2, the temperature of the wafer in the second etching step 1 being lower than that of the wafer in the second modification step 1, and the temperature of the wafer in the second etching step 2 being higher than that of the wafer in the second etching step 1 and lower than that of the wafer in the second modification step 1; and an average temperature of the wafer during etching in the first processing stage is controlled to be less than that of the wafer during etching in the second processing stage.

3. The plasma process method according to claim 2, wherein in the first processing stage and the second processing stage, the temperature of the wafer is less than 20° C.

4. The plasma process method according to claim 1, wherein the source radio frequency and/or the bias radio frequency adopts a pulse mode.

5. The plasma process method according to claim 2, wherein the first processing stage further comprises a first etching step n, a first modification step n and a first etching step n+1, the temperature of the wafer in the first etching step n being lower than that of the wafer in the first modification step n, and the temperature of the wafer in the first etching step n+1 being higher than that of the wafer in the first etching step n and lower than that of the wafer in the first modification step n; and/or the second processing stage further comprises a second etching step n, a second modification step n and a second etching step n+1, the temperature of the wafer in the second etching step n being lower than that of the wafer in the second modification step n, the temperature of the wafer in the second etching step n+1 being higher than that of the wafer in the second etching step n and lower than that of the wafer in the second modification step n, and n being greater than 2; and
in the second processing stage, the second etching step 1 and the second modification step 1 are alternately performed.

6. The plasma process method according to claim 1, wherein durations of the first etching step 1, the first modification step 1 and the first etching step 2 respectively range from 0.5 ms to 100 s, and/or durations of the second etching step 1, the second modification step 1 and the second etching step 2 respectively range from 0.5 ms to 100 s.

7. The plasma process method according to claim 2, wherein the first processing stage uses a same reaction gas, and/or the second processing stage uses a same reaction gas.

8. The plasma process method according to claim 1, wherein the wafer comprises an alternate stacked layer of silicon oxide and silicon nitride, or an alternate stacked layer of silicon oxide and polysilicon, or a silicon oxide layer.

9. The plasma process method according to claim 8, wherein by the process method, a hole with an aspect ratio greater than 40 is formed in the wafer.

10. The plasma process method according to claim 2, wherein the sum of power of the source radio frequency and power of the bias radio frequency applied to the reaction chamber in the first etching step 1 is first etching net power, the sum of power of the source radio frequency and power of the bias radio frequency applied to the reaction chamber in the first modification step 1 is first modification net power, and the first etching net power is less than the first modification net power; and the sum of power of the source radio frequency and power of the bias radio frequency applied to the reaction chamber in the second etching step 1 is second etching net power, the sum of power of the source radio frequency and power of the bias radio frequency applied to the reaction chamber in the second modification step 1 is second modification net power, and the second etching net power is less than the second modification net power.

11. The plasma process method according to claim 1, wherein a duration of the second modification step 1 is greater than that of the first modification step 1.

12. The plasma process method according to claim 2, wherein a longitudinal etching rate of the first etching step 1 is greater than that of the first modification step 1; a longitudinal etching rate of the second etching step 1 is greater than that of the second modification step 1; a transverse etching rate of the first etching step 1 is less than that of the first modification step 1; and a transverse etching rate of the second etching step 1 is less than that of the second modification step 1.

13. The plasma process method according to claim 2, further comprising a plurality of Nth processing stages after the second processing stage, wherein N is greater than 2; the Nth processing stage comprises an Nth etching step 1, an Nth modification step 1 and an Nth etching step 2; and the temperature of the wafer in the Nth etching step 1 is lower than that of the wafer in the Nth modification step 1, and the temperature of the wafer in the Nth etching step 2 is higher than that of the wafer in the Nth etching step 1 and lower than that of the wafer in the Nth modification step 1.

14. A plasma process method, used for etching a wafer and comprising:
moving the wafer onto a base of a reaction chamber, introducing a reaction gas, using a source radio frequency to excite a plasma and then applying a bias radio frequency, and alternately performing an etching step and a modification step for many times, wherein a temperature of the wafer in the modification step is greater than that of the wafer in the etching step, the temperature of the wafer in the next etching step is increased after each etching step and modification step, and the temperature of the wafer in the next etching step is lower than that of the wafer in the previous modification step.

15. The process method according to claim 14, wherein the sum of power of the source radio frequency and power of the bias radio frequency applied to the reaction chamber is etching net power in the etching step, the sum of power of the source radio frequency and power of the bias radio frequency applied to the reaction chamber is modification net power in the modification step, and the etching net power is less than the modification net power.

16. The process method according to claim 14, wherein time of the etching step ranges from 100 ms to 100 s, and/or time of the modification step ranges from 100 ms to 100 s.

17. The process method according to claim 14, wherein after the etching step and the modification step are alternately performed for 10 s to 1000 s, the temperature of the base is increased and then the etching process and the modification process are continuously performed alternately.

18. The process method according to claim 17, wherein the temperature of the base is less than −30° C.

19. The process method according to claim 17, wherein the temperature of the base is increased from 1° C. to 40° C.

20. A plasma processing device, comprising:
a reaction chamber, a reaction space being formed inside the reaction chamber to perform plasma processing;
a gas inlet structure, connected to a plurality of gas sources and configured to introduce a reaction gas into the reaction space;
a radio frequency source, comprising a source radio frequency and a bias radio frequency;
a base, located inside the reaction chamber, an upper surface of the base being configured to support a wafer; and
a controller, configured to control the processing device to perform the process method according to claim 1.
